(19) United States
(12) Patent Application Publication
(10) Pub. No.: US 2016/0238416 A1
(43) Pub. Date: Aug. 18, 2016

(54) POSITION SENSOR PRODUCTION METHOD, AND POSITION SENSOR PRODUCED BY THE METHOD

(71) Applicant: NITTO DENKO CORPORATION, Ibaraki-shi, Osaka (JP)

(72) Inventors: Yusuke Shimizu, Ibaraki-shi (JP); Ryoma Yoshioka, Ibaraki-shi (JP)

(73) Assignee: NITTO DENKO CORPORATION, Ibaraki-shi, Osaka (JP)

(21) Appl. No.: 15/024,562

(22) PCT Filed: Jul. 22, 2014
(86) PCT No.: PCT/JP2014/069291

§ 371 Date: Mar. 24, 2016

(30) Foreign Application Priority Data
Oct. 17, 2013 (JP) 2013-216587
May 15, 2014 (JP) 2014-101372

(51) Int. Cl. G01D 5/353; G03F 7/20; G06F 3/042

(52) U.S. Cl. CPC G01D 5/3538; G06F 3/0421; G03F 7/2022; G06F 2203/04103

(57) ABSTRACT

In a position sensor production method, a photosensitive resin layer of a core formation photosensitive resin is light-exposed to form cores in a lattice pattern portion and in a peripheral pattern portion bent along an outer periphery of the lattice pattern portion and form non-light-path dummy cores in the peripheral pattern portion. Surfaces of the exposed portion of the photosensitive resin layer of the core formation photosensitive resin serving as the cores and the non-light-path dummy cores and an exposed portion are covered with a photosensitive resin layer of a second cladding formation photosensitive resin and, in this state, the core formation photosensitive resin of the unexposed portion and the second cladding formation photosensitive resin of the photosensitive resin layer are mixed together by heating to form a mixture layer. The mixture layer is light-exposed to be cured to form an over-cladding layer.

### TECHNICAL FIELD

The present invention relates to a method of producing a position sensor which optically senses a pressed position, and a position sensor produced by the production method.

### BACKGROUND ART

A position sensor for optically sensing a pressed position has been hitherto proposed (see, for example, PTL 1). The position sensor includes a sheet-form optical waveguide including a plurality of linear light-path cores arranged in two orthogonal directions and a cladding which covers peripheries of the cores, and is configured such that light emitted from a light emitting element is inputted to one-side end faces of the cores to be transmitted through the cores and received on the other-side end faces of the cores by a light receiving element. When a part of a surface of the optical waveguide associated with an orthogonal arrangement of the cores is pressed with a finger or the like, core portions in the pressed part are compressed (the pressed core portions each have a sectional area reduced in a pressing direction) and, therefore, the level of light received by the light-received element is decreased in the cores corresponding to the pressed part. Thus, the position sensor senses the two-dimensional position (coordinates) of the pressed part.

### RELATED ART DOCUMENT

### Patent Document

PTL 1: JP-A-HEI8(1996)-234895

### SUMMARY OF INVENTION

In the conventional position sensor, however, light paths generally linearly extend long distances from the light emitting element to the orthogonal arrangement of the cores. Therefore, the position sensor per se requires a substantial space for installation thereof.

To cope with this, an inventor of the present invention proposed a position sensor which permits space saving, and already filed a patent application for the position sensor (Japanese Application No. 2010-87939). This position sensor includes a lattice pattern core portion. A core portion extending from the light emitting element to the lattice pattern portion and a core portion extending from the lattice pattern portion to the light receiving element are provided in a peripheral portion of the optical waveguide to be bent along the outer periphery of the lattice pattern portion, whereby the space saving of the position sensor is achieved. A surface portion of the optical waveguide provided in association with the lattice pattern core portion is defined as an input region.

However, light is liable to be leaked (scattered) from the bent portions of the peripheral core portions extending along the outer periphery of the lattice pattern core portion. Particularly, if the peripheral core portions are formed as each having a smaller width for further space saving, the bent portions are liable to be acute (to each have a smaller curvature radius). Therefore, the light leakage (scattering) is more liable to occur. If the light is leaked (scattered) from the bent portions of the peripheral core portions, the level of light received by the light receiving element is reduced. In this case, it is impossible to judge whether the reduction in level of received light is attributable to the pressing of the lattice pattern portion (input region) or the bent portions of the peripheral core portions. This makes it impossible to accurately detect the pressed position, requiring improvement.

In view of the foregoing, it is an object of the present invention to provide a method of producing a position sensor which permits space saving and is free from unwanted leakage (scattering) of light from a core portion outside a lattice pattern core portion, and to provide a position sensor produced by the method.

According to a first inventive aspect to achieve the aforementioned object, there is provided a position sensor production method, comprising: fabricating a sheet-form optical waveguide including a plurality of linear light-path cores; and connecting an optical element to end faces of the light-path cores; wherein the optical waveguide fabricating step comprises: forming a first cladding layer; forming a first photosensitive resin layer of a core formation photosensitive resin on a surface of the first cladding layer; light-exposing the first photosensitive resin layer of the core formation photosensitive resin in a predetermined pattern including a lattice pattern portion and a peripheral pattern portion extending from the lattice pattern portion to be bent along an outer periphery of the lattice pattern portion, to form light-path cores in the lattice pattern portion and to form light-path cores and non-light-path dummy cores in the peripheral pattern portion, the light-path cores and the non-light-path dummy cores being defined by portions of the first photosensitive resin layer of the core formation photosensitive resin cured by the light exposure; after the light-exposing step, covering surfaces of the exposed portions of the first photosensitive resin layer of the core formation photosensitive resin serving as the cores and the dummy cores and an unexposed portion of the first photosensitive resin layer of the core formation photosensitive resin with a second photosensitive resin layer of a second cladding formation photosensitive resin; heating the first and second photosensitive resin layers, whereby the core formation photosensitive resin of the unexposed portion of the first photosensitive resin layer and the second cladding formation photosensitive resin of the second photosensitive resin layer are mixed together to form a mixture layer; and light-exposing the mixture layer to cure the mixture layer to form a third cladding layer; wherein the end faces of the light-path cores to be connected to the optical element are end faces of the light-path cores formed in the peripheral pattern portion.

According to a second inventive aspect, there is provided a position sensor produced by the position sensor production method of the first inventive aspect, wherein the non-light-path dummy cores are provided in the peripheral pattern portion bent along the outer periphery of the lattice pattern portion of the light-path cores, and wherein a difference in refractive index between the light-path cores and the third cladding layer present around the light-path cores is greater in a region corresponding to the peripheral pattern portion than in a region corresponding to the lattice pattern portion.

The inventors of the present invention conducted studies on how to prevent the leakage (scattering) of light from the core pattern portion outside the lattice pattern portion in the arrangement in which the core portion optically connecting the lattice pattern core portion to the optical element is provided around the lattice pattern portion and bent along the outer periphery of the lattice pattern portion for the space saving of the position sensor. Then, the inventors conceived an idea that a difference in refractive index between the cores and the cladding present around the cores is made greater in the region corresponding to the peripheral pattern portion around the lattice pattern portion than in the region corresponding to the lattice pattern portion, and further conducted studies on the position sensor production method. As the difference in refractive index increases, the light is less liable to be leaked (scattered) from the cores. In the studies, the inventors conceived an idea that the cladding layer to be kept in contact with the cores is formed by mixing a core formation material having a greater refractive index and a cladding formation material having a smaller refractive index in different volumetric ratios, and further conducted studies. As a result, the inventors found that, where the light-path cores as well as the non-light-path dummy cores are formed in the peripheral pattern portion by curing the (first) photosensitive resin layer of the core formation photosensitive resin on the surface of the (first) cladding layer by the light exposure, and then the third cladding layer is formed by covering surfaces of the exposed portion of the first photosensitive resin layer of the core formation photosensitive resin serving as the light-path cores and the dummy cores and an unexposed portion with the second photosensitive resin layer of the second cladding formation photosensitive resin, mixing together the core formation photosensitive resin of the unexposed portion of the first photosensitive resin layer and the second cladding formation photosensitive resin of the second photosensitive resin layer with heating to form the mixture layer, and curing the mixture layer by the light exposure, a difference in refractive index between the cores and the third cladding layer is made greater in the region corresponding to the peripheral pattern portion than in the region corresponding to the lattice pattern portion to thereby prevent the unwanted light leakage (scattering) in the peripheral pattern portion, and attained the present invention.

Where two materials having different refractive indices are mixed together, the refractive index of the resulting material mixture is intermediate between the refractive indices of the two materials, and closer to the refractive index of one of the two materials having a greater mixing volumetric ratio. In the present invention, therefore, the core formation photosensitive resin is present in a smaller mixing volumetric ratio in the unexposed portion of the first photosensitive resin layer in the peripheral pattern portion than in the lattice pattern portion, because the dummy cores are formed in the peripheral pattern portion. Therefore, the third cladding layer has a refractive index closer to the refractive index of the cured second photosensitive resin layer of the second cladding formation photosensitive resin in the region corresponding to the peripheral pattern portion than in the region corresponding to the lattice pattern portion. That is, the difference in refractive index between the cores and the third cladding layer is greater in the region corresponding to the peripheral pattern portion than in the region corresponding to the lattice pattern portion, so that the unwanted light leakage (scattering) can be prevented in the peripheral pattern portion.

In the inventive position sensor production method, when the light-path cores are formed by light-exposing the first photosensitive resin layer of the core formation photosensitive resin, the non-light-path dummy cores are formed in the peripheral pattern portion by the light exposure of the first photosensitive resin layer. Therefore, when the core formation photosensitive resin of the unexposed portion of the first photosensitive resin layer and the second cladding formation photosensitive resin of the second photosensitive resin layer are thereafter mixed together to form the mixture layer, the core formation photosensitive resin of the unexposed portion is present in a smaller mixing volumetric ratio in the region corresponding to the peripheral pattern portion. Thus, the third cladding layer formed by curing the mixture layer by the light exposure has a smaller refractive index in the region corresponding to the peripheral pattern portion than in the region corresponding to the lattice pattern portion. Therefore, the difference in refractive index between the cores and the third cladding layer is made greater in the region corresponding to the peripheral pattern portion than in the region corresponding to the lattice pattern portion. In addition, it is possible to simultaneously impart these regions with different refractive index differences. As a result, the position sensor thus produced can prevent the unwanted light leakage (scattering) in the peripheral pattern portion, i.e., the position sensor is capable of properly sensing the pressed position.

The inventive position sensor is produced by the aforementioned position sensor production method. In the position sensor, the non-light-path dummy cores are provided in the peripheral pattern portion. Therefore, the difference in refractive index between the light-path cores and the third cladding layer present around the light-path cores is made greater in the region corresponding to the peripheral pattern portion than in the region corresponding to the lattice pattern portion. Thus, the inventive position sensor prevents the unwanted light leakage (scattering) in the peripheral pattern portion, and is capable of properly sensing the pressed position.

### BRIEF DESCRIPTION OF DRAWINGS

FIG. 1A is a plan view schematically showing a position sensor according to one embodiment of the present invention, and FIGS. 1B and 1C are enlarged sectional views showing a center portion and a peripheral portion, respectively, of the position sensor.

FIGS. 2A to 2D are schematic diagrams for explaining a method of fabricating an optical waveguide of the position sensor.

FIG. 3 is an enlarged partial sectional view schematically showing the position sensor in use.

FIGS. 4A to 4F are enlarged plan views each schematically showing an intersecting core portion of lattice pattern cores in the position sensor.

FIGS. 5A and 5B are enlarged plan views each schematically showing light ray paths in an intersecting core portion of the lattice pattern cores.

### DESCRIPTION OF EMBODIMENT

Next, an embodiment of the present invention will be described in detail based on the drawings.

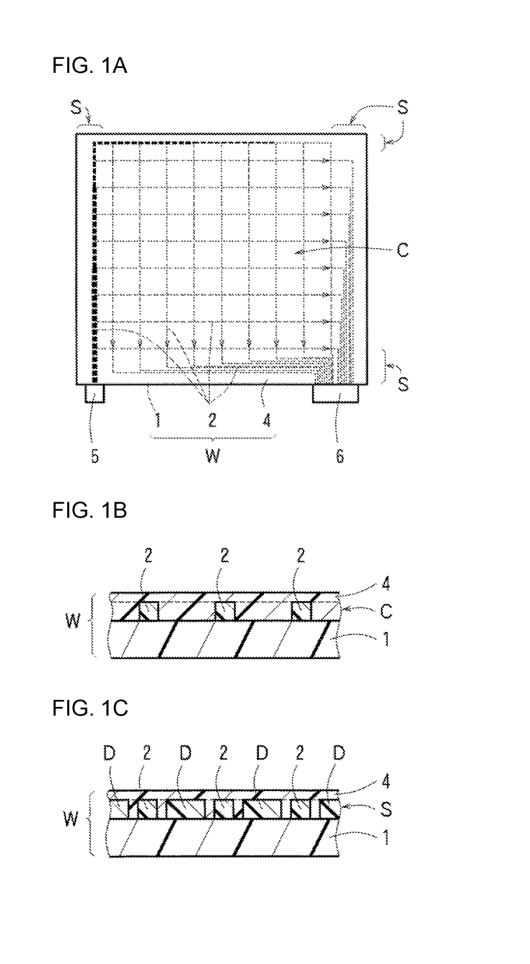

FIG. 1A is a plan view showing a position sensor according to an embodiment of the present invention. FIG. 1B is an enlarged view showing a center portion of the position sensor in section, and FIG. 1C is an enlarged view showing a peripheral portion of the position sensor in section. The position sensor according to this embodiment includes a rectangular sheet-form optical waveguide W, a light emitting element 5, and a light receiving element 6. In the optical waveguide W, a plurality of linear light-path cores 2 are arranged in a pattern including a lattice pattern portion C provided in a center portion of the optical waveguide W and a peripheral pattern portion S extending from the lattice pattern portion C to be bent along the outer periphery of the lattice pattern portion C on a surface of a rectangular sheet-form under-cladding layer (first cladding layer) 1, and non-light-path dummy cores D (not shown in FIG. 1A) formed of the same material as the cores 2 are provided in spaced relation to the cores 2 on a surface portion of the under-cladding layer 1 associated with the peripheral pattern portion S. An over-cladding layer (third cladding layer) 4 is provided over the surface of the under-cladding layer 1 to cover the cores 2 and the dummy cores D. In the optical waveguide W, a difference in refractive index between the light-path cores 2 and the over-cladding layer 4 contacting the light-path cores 2 is greater in a region corresponding to the peripheral pattern portion S than in a region corresponding to the lattice pattern portion C. Further, the light emitting element 5 is connected to one-side end faces of the cores 2 on one side of the peripheral pattern portion S, and the light receiving element 6 is connected to the other-side end faces of the cores 2 on the other side of the peripheral pattern portion S.

In the position sensor, light emitted from the light emitting element 5 is transmitted in the cores 2 from the one side of the peripheral pattern portion S to the other side of the peripheral pattern portion S through the lattice pattern portion C, and is received by the light receiving element 6. A surface portion of the over-cladding layer 4 located in association with the lattice pattern portion C of the cores 2 is defined as an input region. In FIG. 1A, the cores 2 are indicated by broken lines, and the thicknesses of the broken lines correspond to the thicknesses of the cores 2. In FIG. 1A, some of the cores 2 are omitted. In FIG. 1A, arrows each indicate a light traveling direction.

Next, a method of fabricating the optical waveguide W will be described in detail.

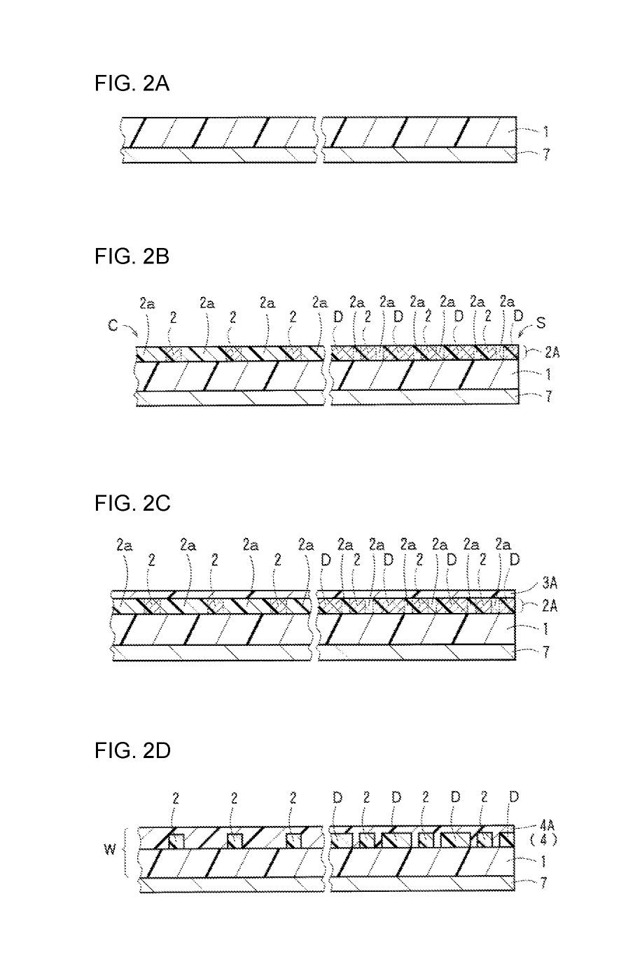

First, a substrate 7 (see FIG. 2A) is prepared. Exemplary materials for the substrate 7 include glass, metals, resins, quartz and silicon.

Then, as shown in FIG. 2A, an under-cladding layer 1 is formed on a surface of the substrate 7. The formation of the under-cladding layer 1 is achieved, for example, by a photolithography process using a photosensitive resin as a material. The under-cladding layer 1 has a thickness of, for example, 20 to 2000 μm.

In turn, as shown in FIG. 2B, a (uncured) photosensitive resin layer 2A of a core formation photosensitive resin is formed on a surface of the under-cladding layer 1. The formation of the photosensitive resin layer 2A is achieved, for example, by a spin coating method, a dipping method, a casting method, an injection method, an ink jet method or the like. The core formation photosensitive resin has a greater refractive index than the under-cladding formation photosensitive resin and a second cladding formation photosensitive resin to be described later. The refractive index may be controlled, for example, by properly selecting the type of the photosensitive resin and adjusting the formulation of the photosensitive resin.

Subsequently, the photosensitive resin layer 2A of the core formation photosensitive resin is exposed to light in a predetermined pattern (as indicated by two-dot-and-dash lines) with a photomask (not shown). At this time, portions of the photosensitive resin layer 2A later serving as the light-path cores 2 are light-exposed in the lattice pattern core portion C (on a left side of FIG. 2B), and portions of the photosensitive resin layer 2A later serving as the light-path cores 2 and the non-light-path dummy cores D are light-exposed in the peripheral pattern portion S (on a right side of FIG. 2B). Thus, the exposed portions of the photosensitive resin layer 2A are cured to form the cores 2 and the dummy cores D. The cores 2 and the dummy cores D each have a thickness of, for example, 5 to 100 μm, and a width of, for example, 5 to 100 μm.

In turn, as shown in FIG. 2C, surfaces of the exposed portions (the cores 2 and the dummy cores D) and an unexposed portion (uncured portion) 2a of the photosensitive resin layer 2A of the core formation photosensitive resin are covered with a (uncured) photosensitive resin layer 3A of a second cladding formation photosensitive resin. The coverage with the photosensitive resin layer 3A is achieved in the same manner as the formation of the photosensitive resin layer 2A of the core formation photosensitive resin described with reference to FIG. 2B.

Then, a heat treatment is performed with the use of a hot plate or the like. By the heat treatment, the core formation photosensitive resin of the unexposed portion 2a of the photosensitive resin layer 2A and the second cladding formation photosensitive resin of the photosensitive resin layer 3A are mixed together by convection therebetween, whereby a mixture layer 4A is formed as shown in FIG. 2D. In order for a homogeneous mixture of the resins of the mixture layer 4A to be formed, the heat treatment is preferably performed at 100° C. to 200° C. for 5 to 30 minutes. If the heat treatment temperature is excessively low or the heat treatment period is excessively short, the mixing will be insufficient. Therefore, an over-cladding layer 4 to be thereafter formed by curing the mixture layer 4A is liable to have uneven formulation, resulting in greater light transmission loss of the cores 2. If the heat treatment temperature is excessively high or the heat treatment period is excessively long, the cores 2 are liable to melt.

Thereafter, the mixture layer 4A is light-exposed to be cured, whereby the over-cladding layer 4 is formed. The over-cladding layer 4 contacts top surfaces and side surfaces of the cores 2. The over-cladding layer 4 has a thickness of, for example, 1 to 200 μm (as measured from the top surfaces of the cores 2 and the dummy cores D) for easy detection of a pressed position.

Thus, the optical waveguide W including the under-cladding layer 1, the cores 2, the dummy cores D and the over-cladding layer 4 is produced on the surface of the substrate 7. The optical waveguide W produced on the surface of the substrate 7 is used in this state, or is separated from the substrate 7 for use. Thereafter, the light emitting element 5 is connected to the one-side end faces of the cores 2 on one side of the peripheral pattern portion S, and the light receiving element 6 is connected to the other-side end faces of the cores 2 on the other side of the peripheral pattern portion S. Thus, the position sensor shown in FIG. 1 is produced.

The over-cladding layer 4 has a refractive index that is intermediate between the refractive index of the photosensitive resin layer 2A of the core formation photosensitive resin and the refractive index of the photosensitive resin layer 3A of the second cladding formation photosensitive resin and is closer to the refractive index of one of these photosensitive resins having a greater mixing volumetric ratio. In the region corresponding to the peripheral pattern portion S in the optical waveguide W, the mixing volumetric ratio of the core formation photosensitive resin of the photosensitive resin layer 2A is smaller than in the region corresponding to the lattice pattern portion C due to the presence of the dummy cores D. Therefore, the refractive index of the over-cladding layer 4 is closer to the refractive index of the photosensitive resin layer 3A of the second cladding formation photosensitive resin in the region corresponding to the peripheral pattern portion S than in the region corresponding to the lattice pattern portion C. That is, the difference in refractive index between the cores 2 and the over-cladding layer 4 is greater in the region corresponding to the peripheral pattern portion S than in the region corresponding to the lattice pattern portion C. Thus, unwanted light leakage (scattering) can be prevented in the peripheral pattern portion S. In addition, it is possible to simultaneously impart these regions with different refractive index differences (during the formation of the over-cladding layer 4).

In the method of fabricating the optical waveguide W, the side surfaces of the cores 2 are often roughened by the light exposure with the photomask in the formation of the cores 2. The rough side surfaces of the cores 2 adversely influence the light transmission in the cores 2. In a conventional optical waveguide fabrication method, the rough side surfaces of the cores 2 remain because the unexposed portion 2a is dissolved away by development. In the optical waveguide W according to this embodiment, as described above, the unexposed portion 2a is left without the development, and the core formation photosensitive resin of the unexposed portion 2a is mixed with the second cladding formation photosensitive resin of the photosensitive resin layer 3A with heating. Therefore, the mixture layer is formed in interfaces between the cores 2 and the photosensitive resin layer 3A of the second cladding formation photosensitive resin, so that the roughening of the side surfaces of the cores 2 can be prevented. This effectively reduces the light transmission loss.

In this embodiment, the cores 2 have a greater elasticity modulus than the under-cladding layer 1 and the over-cladding layer 4. Thus, when the input region of the rectangular sheet-form optical waveguide W is pressed, the cores 2 are deformed at a smaller deformation rate in section in the pressing direction than the over-cladding layer 4 and the under-cladding layer 1. The term “deformation rate” herein means the percentage of a change in the thickness of the cores 2, the over-cladding layer 4 or the under-cladding layer 1 in the pressing direction based on the original thickness thereof before the pressing.

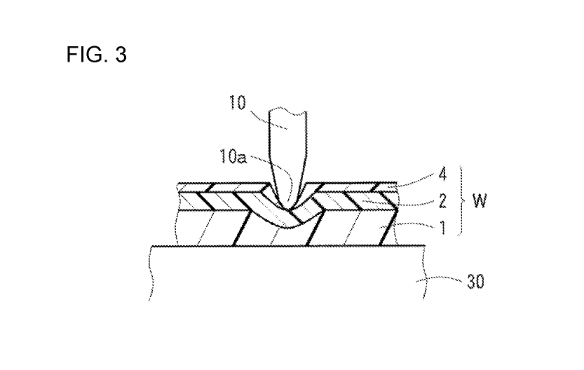

As shown in a sectional view of FIG. 3, for example, the position sensor is placed on a planar base 30 such as a table and, in use, information such as a character is written on the surface portion of the over-cladding layer 4 located in association with the lattice pattern core portion C (input region) by means of an input element 10 such as a pen. In the writing, the surface of the over-cladding layer 4 of the optical waveguide W is pressed with an input tip portion 10a such as a pen tip. In a part of the position sensor pressed with the input tip portion 10a (the pen tip or the like), a core portion 2 is bent along the input tip portion 10a (the pen tip or the like) to sink in the under-cladding layer 1. Light is leaked (scattered) from the bent core portion 2. Therefore, the light receiving element 6 (see FIG. 1A) detects reduction in light detection level in the core portion 2 pressed with the input tip portion 10a (the pen tip or the like). The position sensor can sense the position (coordinates) and the movement locus of the input tip portion 10a (the pen tip or the like) based on the reduction in light detection level.

In this embodiment, as described above (with reference to FIGS. 2C and 2D), the over-cladding layer 4 is formed by mixing together the core formation photosensitive resin of the unexposed portion 2a of the photosensitive resin layer 2A and the second cladding formation photosensitive resin of the photosensitive resin layer 3A to form the mixture layer 4A and curing the mixture layer 4A. Therefore, the refractive index of the over-cladding layer 4 is closer to the refractive index of the cores 2 than the refractive index of a conventional cladding layer formed only from the second cladding formation resin for the photosensitive resin layer 3A. That is, the difference in refractive index between the cores 2 and the over-cladding layer 4 is reduced as compared with the conventional case. Therefore, as described above, the light is more liable to be leaked (scattered) from the cores 2 in the part of the input region pressed with the input tip portion 10a such as the pen tip (see FIG. 3), so that the pressed position can be detected with a higher sensitivity.

When information such as a character is written on the input region of the position sensor with the input element 10 (the pen or the like) with the position sensor connected to a display device and/or a personal computer (hereinafter referred to as “PC”) wirelessly or via a connection cable, the position and the movement locus of the input tip portion 10a (the pen tip or the like) can be displayed on the display device (or a display of the PC). Where the position sensor is provided with storage means such as a memory, the information (character and the like) can be stored in the form of digital data in the storage means, and thereafter reproduced (displayed) by a reproduction terminal (PC, a mobile terminal or the like). Further, the information can be stored in the reproduction terminal.

The optical waveguide W of the position sensor may have a construction different from that shown in the aforementioned embodiment. For example, the optical waveguide W may have a construction inverted from that shown in FIGS. 1B and 1C. In this case, portions of the cladding layer present on the top surfaces of the cores 2 each have a smaller thickness, e.g., a thickness of 1 to 200 μm, as in the case of the aforementioned over-cladding layer 4.

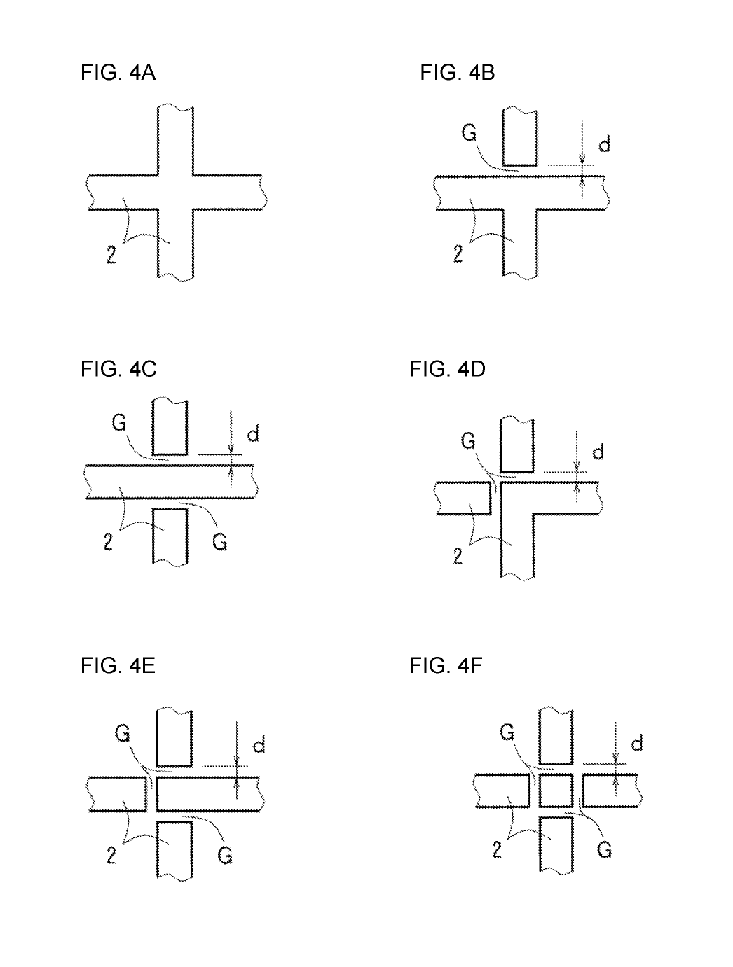

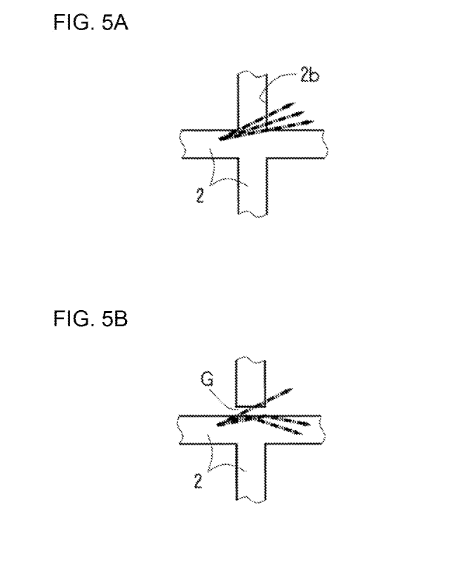

In the aforementioned embodiment, intersecting core portions of the cores 2 arranged in the lattice pattern typically each continuously extend in four intersecting directions as shown in an enlarged plan view of FIG. 4A, but may be configured in other ways. For example, as shown in FIG. 4B, a part of the intersecting core portion may be discontinuous and separated in one of the intersecting directions from the other part of the intersecting core portion by a gap G. The gap G is filled with the material for the under-cladding layer 1 or the over-cladding layer 4. The gap G has a width d that is greater than 0 (zero) (sufficient to form the gap G) and typically not greater than 20 μm. Similarly, as shown in FIGS. 4C and 4D, two parts of the intersecting core portion may be discontinuous in two of the intersecting directions (in two opposite directions in FIG. 4C, or in two adjacent directions in FIG. 4D) from the other part of the intersecting core portion. Further, as shown in FIG. 4E, three parts of the intersecting core portion may be discontinuous in three of the intersecting directions from the other part of the intersecting core portion. As shown in FIG. 4F, four parts of the intersecting core portion may be discontinuous in all the four intersecting directions from the other part of the intersecting core portion. Further, the cores 2 may be arranged in a lattice pattern including two or more of the aforementioned types of intersecting core portions shown in FIGS. 4A to 4F. In the present invention, the lattice pattern defined by the plurality of linear cores 2 is herein meant to include intersecting core portions some or all of which are configured in any of the aforementioned manners.

Whereat least one part of the intersecting core portion is discontinuous in at least one of the intersecting directions from the other part of the intersecting core portion as shown in FIGS. 4B to 4F, intersection light loss can be reduced. In an intersecting core portion continuously extending in all the four intersecting directions, as shown in FIG. 5A, light traveling through a core 2 orthogonally intersecting a specific core 2 extending in one of the intersecting directions (in an upward direction in FIG. 5A) is incident on the intersecting core portion to partly reach a wall surface 2a of the specific core 2, and goes out of the specific core 2 (as indicated by arrows of two-dot-and-dash lines in FIG. 5A) because of greater reflection angles on the wall surface 2a. Similarly, light goes out of apart of the specific core 2 extending in a direction opposite from the aforementioned direction (in a downward direction in FIG. 5A). Where apart of the intersecting core portion is discontinuous in one of the intersecting directions (in an upward direction in FIG. 5B) from the other part of the intersecting core portion in the presence of a gap G, as shown in FIG. 5B, an interface is defined between the gap G and the core 2 and, therefore, the light transmitted through the core 2 in FIG. 5A is partly reflected at smaller reflection angles on the interface without passing through the interface, and continuously travels through the core 2 (as indicated by arrows of two-dot-and-dash lines in FIG. 5B). Therefore, where at least one part of the intersecting core portion is discontinuous in at least one of the intersecting directions from the other part of the intersecting core portion, as described above, the intersection light loss can be reduced. As a result, the pressed position at which the input region is pressed with the pen tip or the like can be detected with a higher detection sensitivity.

Next, an inventive example will be described in conjunction with a conventional example. It should be understood that the invention be not limited to the inventive example.

### EXAMPLE

### Under-Cladding Formation Material

Component (a): 60 parts by weight of an epoxy resin (YL7410 available from Mitsubishi Chemical Corporation)
Component (b): 40 parts by weight of an epoxy resin (EHPE3150 available from Daicel Corporation)
Component (c): 4 parts by weight of a photo-acid generator (CPI101A available from San-Apro Ltd.)

An under-cladding formation material was prepared by mixing Components (a) to (c). The under-cladding formation material has a refractive index of 1.496 as measured at a wavelength of 830 nm. A prism coupler (SPA-4000 available from SAIRON TECHNOLOGY, Inc.) was used for the measurement of the refractive index. (In the following, the refractive index was measured in the same manner.)

[Core Formation Material]

Component (d): 10 parts by weight of an epoxy resin (JER1002 available from Mitsubishi Chemical Corporation)
Component (e): 90 parts by weight of an epoxy resin (EHPE3150 available from Daicel Corporation)
Component (f): 1 part by weight of a photo-acid generator (SP170 available from ADEKA Corporation)
Component (g): 50 parts by weight of ethyl lactate (solvent available from Wako Pure Chemical Industries, Ltd.)

A core formation material was prepared by mixing Components (d) to (g). The core formation material had a refractive index of 1.516 as measured at a wavelength of 830 nm.

[Second Cladding Formation Material]

Component (h): 100 parts by weight of an epoxy resin (YL7410 available from Mitsubishi Chemical Corporation)
Component (i): 4 parts by weight of a photo-acid generator (CPI101A available from San-Apro Ltd.)

A second cladding formation material was prepared by mixing Components (h) and (i). The second cladding formation material has a refractive index of 1.472 as measured at a wavelength of 830 nm.

[Fabrication of Optical Waveguide]

An optical waveguide was fabricated by the method according to the aforementioned embodiment. When the over-cladding layer was formed, the mixing volumetric ratio between the core formation material of the unexposed portion and the second cladding formation material was 25/18 in the region corresponding to the lattice pattern core portion, and was 10/21 in the region corresponding to the peripheral pattern portion.

The refractive index of the over-cladding layer formed in the aforementioned manner was 1.496 in the region corresponding to the lattice pattern core portion, and was 1.486 in the region corresponding to the peripheral pattern portion. This means that the difference in refractive index between the cores and the over-cladding layer was greater in the region corresponding to the peripheral pattern portion than in the region corresponding to the lattice pattern portion.

### Conventional Example

An optical waveguide was fabricated in substantially the same manner as in the inventive example, except that only core portions of the core formation material layer were light-exposed but dummy core portions of the core formation material layer were not light-exposed in the formation of the cores, that the unexposed portion was dissolved away by the development after the light exposure, and that the over-cladding layer was formed by applying the second cladding formation material and light-exposing the resulting second cladding formation material layer. More specifically, the dummy cores were not formed, and the core formation material of the unexposed portion and the second cladding formation material were not mixed together.

In Conventional Example, therefore, the difference in refractive index between the cores and the over-cladding layer (cladding layer formed only from the second cladding formation material) was constant in the region corresponding to the peripheral pattern portion and in the region corresponding to the lattice pattern portion.

While a specific form of the embodiment of the present invention has been shown in the aforementioned inventive example, the inventive example is merely illustrative of the invention but not limitative of the invention. It is contemplated that various modifications apparent to those skilled in the art could be made within the scope of the invention.

The inventive position sensor permits the space saving, and is free from the unwanted light leakage (scattering) and capable of accurately detecting the pressed position.

### REFERENCE SIGNS LIST

C: Lattice pattern portion
S: Peripheral pattern portion
D: Dummy cores
2: Cores
2A: Photosensitive resin layer of core formation photosensitive resin
2a: Unexposed portion
3A: Photosensitive resin layer of second cladding formation photosensitive resin
4: Over-cladding layer
4A: Mixture layer

1. A position sensor production method comprising:
fabricating a sheet-form optical waveguide including a plurality of linear light-path cores; and
connecting an optical element to end faces of the light-path cores;
wherein the optical waveguide fabricating step comprises:
forming a first cladding layer;
forming a first photosensitive resin layer of a core formation photosensitive resin on a surface of the first cladding layer;
light-exposing the first photosensitive resin layer of the core formation photosensitive resin in a predetermined pattern including a lattice pattern portion and a peripheral pattern portion extending from the lattice pattern portion to be bent along an outer periphery of the lattice pattern portion, to form light-path cores in the lattice pattern portion and to form light-path cores and non-light-path dummy cores in the peripheral pattern portion, the light-path cores and the non-light-path dummy cores being defined by portions of the first photosensitive resin layer of the core formation photosensitive resin cured by the light exposure;
after the light-exposing step, covering surfaces of the exposed portions of the first photosensitive resin layer of the core formation photosensitive resin serving as the cores and the dummy cores and an unexposed portion of the first photosensitive resin layer of the core formation photosensitive resin with a second photosensitive resin layer of a second cladding formation photosensitive resin;
heating the first and second photosensitive resin layers, whereby the core formation photosensitive resin of the unexposed portion of the first photosensitive resin layer and the second cladding formation photosensitive resin of the second photosensitive resin layer are mixed together to form a mixture layer; and
light-exposing the mixture layer to cure the mixture layer to form a second cladding layer;
wherein the end faces of the light-path cores to be connected to the optical element are end faces of the light-path cores formed in the peripheral pattern portion.

2. A position sensor produced by the position sensor production method according to claim 1, wherein the non-light-path dummy cores are provided in the peripheral pattern portion bent along the outer periphery of the lattice pattern portion of the light-path cores, and
wherein a difference in refractive index between the light-path cores and the second cladding layer present around the light-path cores is greater in a region corresponding to the peripheral pattern portion than in a region corresponding to the lattice pattern portion.
